(19) United States
(12) Patent Application Publication
(10) Pub. No.: US 2021/0088601 A1
(43) Pub. Date: Mar. 25, 2021

(54) HIGH PRESSURE MAGNETO-RESISTIVE NON-CONTACT DISPLACEMENT SENSOR

(71) Applicant: Kaman Aerospace Corporation, Memory and Measuring Systems, Middletown, CT (US)

(72) Inventors: Scott HARDER, Colorado Springs, CO (US); Paddy COLLINS, Colorado Springs, CO (US); Jake BOGENSCHUTZ, Colorado Springs, CO (US)

(21) Appl. No.: 17/025,222

(22) Filed: Sep. 18, 2020

Related U.S. Application Data
(60) Provisional application No. 62/903,284, filed on Sep. 20, 2019.

(51) Int. Cl. G01R 33/00; G01D 5/14; G01R 33/09

(52) U.S. Cl. CPC G01R 33/0011; G01R 33/091; G01D 5/145

(57) ABSTRACT

A sensor system includes: a sensor insert sub-assembly including a sensor holder, a biasing magnet connected to the sensor holder, and a first sensor connected to the sensor holder, wherein a first end of the sensor housing insert sub-assembly is configured to face a target; and a pressure barrier connected to the sensor insert sub-assembly. A portion of the pressure barrier extends between the first end of the sensor housing insert sub-assembly and the target. There is a gap between the portion of the pressure barrier and the first end of the sensor insert sub-assembly. The first sensor includes a magneto-resistive sensor that is configured to detect a displacement of the target relative to the sensor housing insert sub-assembly.

### FIELD OF THE INVENTION

Aspects of the present invention relate generally to non-contact displacement sensors and, more particularly, to Magneto Resistive (MR) sensors configured for non-contact displacement measurement applications.

### BACKGROUND

Several measurement solutions exist for in situ displacement measurement at operating pressures up to 8,250 psi. Examples of high-pressure capable solutions include, laser, capacitive, eddy current, linear variable differential transformers (LVDT), and fluid backed, pressure-compensating sensors. However, each of these displacement sensing technologies has characteristics limiting their economy and effectiveness in high pressure industrial environments. Non-contact laser sensing solutions are expensive, and their performance limited by the transparency and thickness of the pressure barrier, the transparency and homogeneity of the working fluid, as well as cavitation, a common but undesirable occurrence in high speed fluid handling systems. Non-contact capacitive sensor performance depends on a steady dielectric constant between the sensor and the target making capacitive techniques susceptible to noise and interference due to non-homogeneities in the working fluid. Additionally, the measuring range of a capacitive sensor is proportional to the size of the sensor, a potential limiting factor for high precision operation in pressurized environments where minimizing the size to range ratio is important. Glass sealed eddy current sensors are known to have rated operating pressures up to 8,250 psi, and some claim robustness to pressures up to 29,000 psi. However, like their capacitive cousins, eddy current sensor measurement range depends on the diameter of the sensor. Additionally, the physics of eddy current sensing restricts the list of construction materials. LVDT sensors can operate at very high pressures but require contact with the target and are therefore a solution of last resort in situations where a non-contact technology is preferred but is either cost prohibitive or unable to meet performance or environmental requirements. Fluid backed, pressure-compensating sensors can accommodate various contact and non-contact sensing technologies; however, in addition to operational limitations of the technology employed, the sensor itself must be cable of withstanding the static pressure.

### SUMMARY

In a first aspect of the invention, there is a sensor assembly including: a sensor insert sub-assembly comprising a sensor holder, a biasing permanent or electro-magnet connected to the sensor holder, and a first MR sensor connected to the sensor holder, wherein a first end of the sensor insert sub-assembly is configured to face a target; within a pressure barrier connected to the sensor insert sub-assembly. A portion of the pressure barrier extends between the first end of the sensor insert sub-assembly and the target. There is a gap between the portion of the pressure barrier and the first end of the sensor insert sub-assembly. The first sensor comprises a magneto-resistive sensor that is configured to detect displacement of a Ferro-magnetic target relative to the sensor insert sub-assembly.

In another aspect of the invention, there is a method including using the sensor system to detect the displacement of the target.

In another aspect of the invention, there is a method including manufacturing the sensor system.

### BRIEF DESCRIPTION OF THE SEVERAL VIEWS OF THE DRAWINGS

Aspects of the present invention are described in the detailed description which follows, in reference to the noted plurality of drawings by way of non-limiting examples of exemplary embodiments of the present invention.

FIG. 1 shows a sensor assembly in accordance with aspects of the invention.

FIG. 2 shows a magnified view of a portion of the sensor system of FIG. 1.

FIG. 3 shows an embodiment of a sensor system in accordance with aspects of the invention.

FIG. 4 shows an embodiment of a sensor system in accordance with aspects of the invention.

FIG. 5 shows an embodiment of a sensor system in accordance with aspects of the invention.

FIG. 6 shows an embodiment of a sensor system in accordance with aspects of the invention.

FIG. 7 shows an embodiment of a sensor system in accordance with aspects of the invention.

FIGS. 8A-E show aspects of a sensor holder that may be used with a sensor system in accordance with aspects of the invention.

### DETAILED DESCRIPTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

Aspects of the present invention relate generally to displacement sensors and, more particularly, to Magneto Resistive (MR) displacement sensors. A challenge presented by high pressure sensing applications is specifying a material of adequate strength that is compatible with an appropriate sensing method for a given set of environmental, reliability, and precision requirements. Given limited sensing options for industrial equipment condition monitoring and motion control at high pressures, subsea pump and other industrial rotating and/or linear motion equipment designers seek instrumentation capable of operating up to and beyond 22,500 psi. As a result of identifying this industry need for a high reliability, high pressure, non-contact sensor, the inventors have designed a tailorable, MR-based sensor assembly capable of withstanding proof pressures of up to at least 40,000 psi. When properly configured, a magnetically biased MR sensor in accordance with aspects of the invention detects the position of a ferro-magnetic target through a non-magnetic barrier material with micron level resolution. Embodiments of the sensor design described herein address several shortcomings of the technologies described above. For example, embodiments can detect magnetic targets through conductive and non-conductive, non-magnetic barriers. Embodiments are not affected by non-homogeneous working fluids or cavitation. And, compared with other technologies, size is not dictated by range but rather by the structural requirements of the sensor housing and integration requirements.

Embodiments of the invention described herein solve the non-contact displacement sensing problem for subsea, cryogenic, corrosive, and other closed or open environments with gauge pressures from atmospheric to 40,000 psi with a linear measurement range of up to 7 mm and a root mean square (RMS) full scale resolution up to 1 micron. Implementations described herein are useable in a number of industrial, commercial, or other applications, including but not limited to: magnetic field measurement, distance measurement, navigation, oil and gas, deep sea, engine dynamics, and rocket engine dynamics.

Currently available displacement sensors do not provide the desired combination of: (i) high reliability; (ii) high pressure (e.g., operability in environments up to 40,000 psi); and (iii) non-contact (e.g., the sensor does not contact the target surface). For example, in instances where a pressurized vessel has a transparent window, laser-based systems have been used to measure position of rotating, vibrating, and other stationary or moving targets such as a shafts, rods, turbine blades, pump vanes, plates, and sheets. In another example, a glass sealed eddy-current sensor operates at pressures up to 8,250 psi. In yet another example, a pressure compensated subsea sensor assembly is useable with several sensing technologies provided the sensor itself can withstand the pressure statically, ether by the inherent nature of its construction or by some method of encapsulation. In still another example, Linear Variable Differential Transformer (LVDT) position sensors operate at pressures of 35,000 psi, but must have contact with the target surface. Some pressure capable sensors involve steel or Inconel housings containing an eddy current sensing element; however, the physics of eddy current sensors prevent steel housings with face thicknesses adequate to support pressure loads greater than 5,000 psi. The maximum working pressure of an eddy current sensor decreases with increasing measuring range as coil diameter increases proportionally to range. In some instances, a coil may be integral to a non-conductive load bearing surface, in which case the sensing coil may be subject to destructive environmental factors and deformation leading to failure or changes in output not related to the intended measurement.

Aspects of the invention address the problem of high-pressure measurement by providing an integrated pressure barrier between the sensor and the environment. In embodiments, there is physical separation (e.g., a gap) between the sensing element and the pressure barrier such that deflection of the pressure barrier due to external loading within the design range does not interfere with the measurement or cause damage to the sensing elements. As a result, there is structural independence of the sensor insert subassembly from the load bearing structure (e.g., the pressure barrier). In this manner, any deflection of the load bearing structure (e.g., the pressure barrier) is independent of the sensor element and does not affect sensor output.

In embodiments, the sensor does not require a permanently magnetized target such as an electromagnet or a permanent magnet. However, this does not preclude the use of an electro or permanent magnet as a target. Moreover, the sensor does not depend on the movement of the sensor with respect to a fixed magnetic field source. Instead, in embodiments, the sensor and the magnetic field source may be stationary relative to one another, e.g., in a passive configuration.

Embodiments of the invention need not depend on an array of sensors or movement of a magnetic target between two distinctly spaced magneto resistive sensors, nor is it required that the sensor be in or below the path of motion or require visibility of target edges, although such attributes are not precluded. Embodiments may be directed to a passive arrangement in which the biasing magnet is not on the target. Embodiments may also be directed to an active arrangement in which the biasing magnet is on the target.

Embodiments of the invention also need not require the use of a toroidal or otherwise non-standard magnet geometry, and instead are useable with both commercially available permanent magnets and electromagnetic biasing sources.

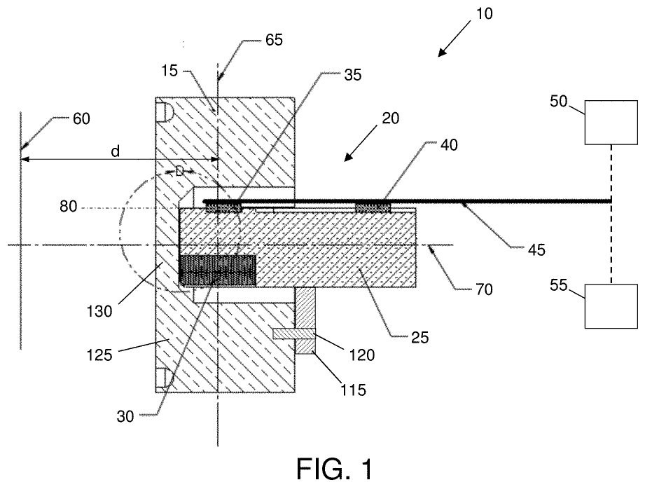

FIG. 1 shows a high-pressure embodiment with one end open to the atmosphere. As such, this embodiment is integral to a pressure barrier or pressure capable assembly. The pressure barrier (sensor housing) encloses the sensor insert sub-assembly. In other embodiments, the sensor housing fully encloses the sensor insert subassembly in a fully hermetic fashion. This construction is suitable also for installation into multi-axis sensor array structures designed to withstand submersion in high-pressure environments. Such an embodiment may be used in rotating machinery condition monitoring applications where there are two radial and one axial sensor installed into a quarter or half disk housing, mounted to a shaft bearing assembly.

In particular, FIG. 1 shows a sensor system 10 in accordance with aspects of the invention, the sensor system 10 including a pressure barrier 15 (also referred to as a barrier) and a sensor housing insert sub-assembly 20. In embodiments, the sensor housing insert sub-assembly 20 comprises a sensor holder 25, a biasing permanent or electro-magnet 30 connected to the sensor holder 25, and a first sensor 35 (also referred to as a primary sensor) also connected to the sensor holder 25. A second sensor 40 (also referred to as a compensating sensor) may optionally be connected to the sensor holder 25 in some embodiments. In aspects, the first sensor 35 (and the second sensor 40, if present) are operatively connected to a signal conducting element 45 that is, in turn, operatively connected to a signal conditioning electronics or data storage device 50 (e.g., signal conditioning hardware or a microprocessor-based digital signal processing application with memory or storage) that processes and stores sensor output data. Additionally, or alternatively, the signal conducting element 45 may be operatively connected to a display device 55 (e.g., a computer-based display device) that outputs a visual display based on the output of the sensor(s).

In implementations, the first sensor 35 comprises a magneto resistive (MR) sensor. In particular embodiments, the first sensor 35 comprises a tunneling magneto resistance (TMR) sensor. In one example, the first sensor 35 includes a commercially available sensor package that uses a push-pull Wheatstone bridge composed of four unshielded MR sensor elements, which provides a highly sensitive differential output proportional to the direction and magnitude of an applied magnetic field. Implementations of the invention are not limited to this particular type of sensor, and other types of MR sensor may be used. The second sensor 40, when used, may be identical to, or different from, the first sensor 35.

Generally speaking, magneto resistance (MR) sensor elements have a resistance change proportional to the magnitude and direction of an applied magnetic field. In this manner, MR sensors detect the presence and intensity of an external magnetic field.

In embodiments, the first sensor 35 is a MR sensor that is configured to detect the position of a target 60, such as a rotating, vibrating, or moving element, such as a shaft, rod, plate, sheet, etc. In a particular embodiment, the target 60 is composed of (or comprises) a magnetic material, and the biasing magnet 30 mounted near the first sensor 35 generates a biasing magnetic field. In aspects, the biasing magnetic field magnetizes the magnetic material of the target 60 and this magnetization of the target 60 increases the total magnetic field at the first sensor 35. The amount of magnetization of the target 60 depends on the relative permeability of the material of the target 60 and also on the distance “d” from the target 60 to the bias field source (i.e., the biasing magnet 30). As a result, a change of position of the target 60 relative to the biasing magnet 30 causes a change in the magnetic field that is sensed by the first sensor 35. In this manner, the output of the first sensor 35 (which in some cases is a voltage measured in millivolts) changes based on a change of position of the target 60 relative to the biasing magnet 30, such that the output of the first sensor 35 is a measure of the position of the target 60 relative to the magnetic field axis 65 of the biasing magnet 30. In a particular embodiment, the first sensor 35 and the biasing magnet 30 are mounted in a fixed position near the target 60, and are used to detect movement of the target 60 relative to that fixed position, e.g., wobble of a rotating shaft, etc.

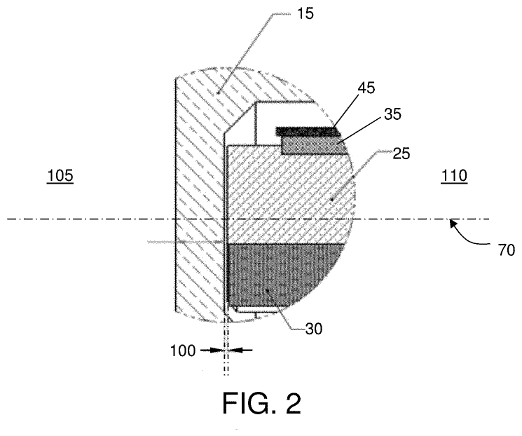

FIG. 2 shows a magnified view of a portion of the sensor system of FIG. 1 shown by the detail circle labeled “D” in FIG. 1. FIG. 2 illustrates the structural independence of the sensor housing insert sub-assembly 20 from the pressure barrier 15. In particular, as shown in FIG. 2, there is a gap 100 between the pressure barrier 15 and the sensor housing insert sub-assembly 20 comprising the sensor holder 25, the biasing magnet 30, and the first sensor 35. In embodiments, the pressure barrier 15 is structured and arranged such that it does not deflect more than the distance of the gap 100 when a differential pressure across the pressure barrier 15 is less than or equal to 40,000 psi. In one example, the gap 100 has a dimension in a range of 1 mil to 20 mils in the direction of axis 70, and the pressure barrier 15 is constructed of a material and with a geometry such that the pressure barrier 15 does not deflect into contact with the sensor housing insert sub-assembly 20 when there is a 40,000 psi pressure on the external side 105 of the pressure barrier 15 relative to the internal side 110 of the pressure barrier 15.

With continued reference to both figures, FIG. 1 shows one possible configuration for the locations of the first sensor 35 and the at least one second sensor 40 in accordance with aspects of the invention. In this configuration, a predefined distance separates the sensors 35, 40 such that the second sensor 40 does not sense, to any significant degree, the interaction between the biasing magnet 30 and the target 60. As such, the second sensor 40 acts as a magnetic field cancelation device for external field disturbances. In this manner, in one example, the outputs of the first sensor 35 and the second sensor 40 are combined (e.g., the second is subtracted from the first) to determine a true reading of the detected position of the target, wherein the reading is a true reading because it is corrected for ambient magnetic field disturbances. Aspects of the invention are not limited to subtraction, and other functions of the first sensor 35 and the second sensor 40 may be used to determine the true reading. Analog-based magnetic field disturbance rejection methods work best in the linear output range of the sensor. In one example, when the linear range of a magneto resistive sensor is 100 Gauss, then the maximum total field, being the signal of interest plus the disturbance, should not exceed 100 Gauss. In this manner, if the signal of interest has an expected peak value of 75 Gauss, the maximum disturbance allowed is 25 Gauss.

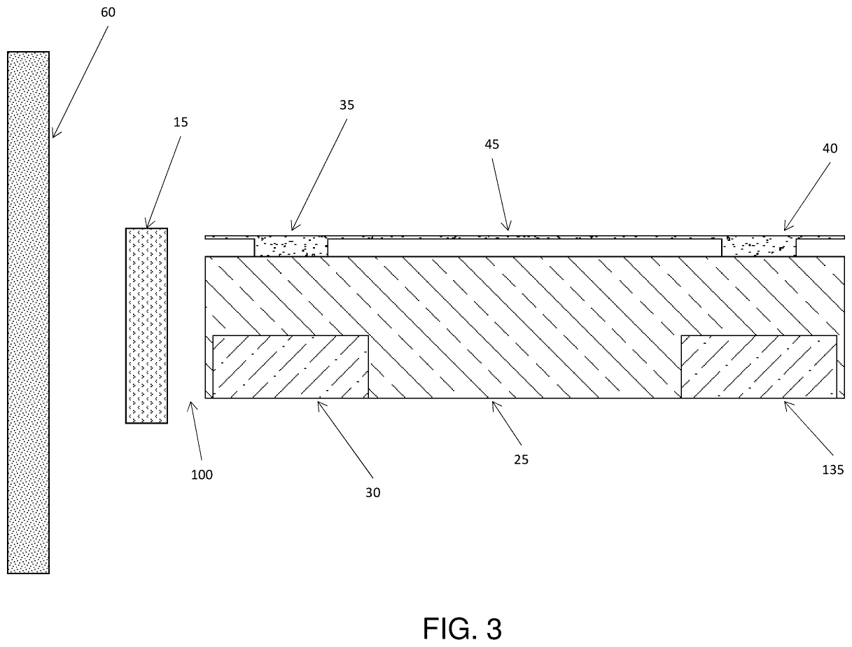

In some embodiments, to improve the magnetic field cancelation attributes, a second biasing magnet 135 (shown in FIG. 3) is placed under the second sensor 40. In this embodiment, the second sensor 40 and its biasing magnet are positioned sufficiently far enough away from the target 60 so that they do not interact (e.g., do not sense the magnetic field generated by the biasing magnet 30 and the target 60). In particular embodiments, the first sensor 35 and the second senor 40 have respective response curves that electrically match one another. In some embodiments, the sensors 35 and 40 function only in their linear ranges as described herein, and an offset and/or gain may be used for matching of the sensor response curves.

According to one exemplary embodiment of the invention, and as shown in FIG. 1, the electromagnetic axis 65 of the biasing magnet 30 is perpendicular to the plane containing the easy axis 80 of the MR element (i.e., the first sensor 35). In this example, the easy axis 80 of the MR element (i.e., the first sensor 35) is parallel to the principal axis of motion 70 of the target 60. In this example, the easy axis 80 of the MR element (i.e., the first sensor 35) is parallel to the easy axis of the second MR element (i.e., the second sensor 40).

Still referring to FIGS. 1 and 2, in embodiments for sensing in one direction (e.g., movement of the target along axis 70), the sensor system 10 comprises at least one magneto-resistive sensor (e.g., first sensor 35), which may be a single magneto resistive element, a half bridge voltage divider, or a full Wheatstone bridge providing a differential output. Extending the technique to multiple and specific directions can be accomplished by putting as many oriented systems together as needed to obtain measurements in all the desired directions whether independently or integrated into a single system. Either a permanent magnet or an oscillating electromagnet (e.g., biasing magnet 30) biases the first sensor 35. A second sensor 40, for cancelling ambient magnetic field disturbances, can be included to reduce the effects of small magnetic field disturbances in a digital based system.

In embodiments, the first and second sensors 35, 40 are mounted on a circuit board (e.g., signal conducting element 45) of any kind such that their orientations are consistent with respect to the easy axis of the first sensor 35. In one example, the easy axis of the first sensor 35 has a vector component perpendicular to a surface of the target 60 and a vector component collinear to the direction of target motion (e.g., along axis 70).

In accordance with aspects of the invention, for common mode external magnetic field disturbance and noise rejection, the second sensor 40 matches the magnetically biased response of the first sensor 35 such that environmental disturbances that do not result in saturation are compensated for the output signal. This reduces system sensitivity to environmental magnetic field noise and disturbances, which are generally uniform over small length scales, such as those encountered near an electric motor or power transmission line.

In embodiments, since the range of the sensor is limited by the spatial extent of the detectible interaction between the magnetic material of the target 60 and the biasing magnetic field generated by the biasing magnet 30, the first and second sensors 35, 40 are separated by a distance at least as large, but preferably greater than, the maximum operational range of the sensor system.

In some implementations, the signal conducting element 45 comprises a printed circuit board (PCB) that is part of a single or multi-piece sensor housing insert sub-assembly 20, the sensor holder 25 of which may be made from non-magnetic material, which may be electrically conductive or non-conductive, and which may comprise materials such as cast or machined ceramics, aluminum, titanium, nickel alloys, stainless steel, plastic or other non-magnetic material. In embodiments, the orientation of the PCB is such that the MR element of the first sensor 35 is facing downward in the sensor holder 25, with its easy axis 80 being perpendicular to the biasing magnetic field axis 65 and parallel to the direction of motion of the target 60 along axis 70. The signal conducting element 45 is not limited to a PCB, and can be any suitable signal conducting element (or elements) that operatively connect the sensors to the signal conditioning electronics, including but not limited to rigid circuit board, flex circuit board, wire, and combinations thereof.

According to aspects of the invention, the biasing field source (e.g., the biasing magnet 30) is ether an opposite pole permanent or electromagnet. The electromagnet can be DC or AC. In high precision cases, it may be desirable to add a third magneto resistive sensor to monitor and regulate the strength of an electromagnetic field. In preferred embodiments, the biasing field source is installed in the holder directly below the MR element of the first sensor 35 such that the pole face is perpendicular to the plane of the MR element of the first sensor 35.

In embodiments, the biasing field source (e.g., the biasing magnet 30), the sensor PCB, and the sensor holder 25 are comprised in the sensor insert sub-assembly 20. In embodiments, the sensor holder 25 is composed of non-magnetic material.

In embodiments, the pressure barrier 15 is composed of non-magnetic material. In a particular embodiment, the pressure barrier 15 is a high strength, non-magnetic housing of either a conductive or non-conductive type. As used herein, the term “magnetic material” refers to a ferromagnetic material, and the term “non-magnetic material” refers to a non-ferromagnetic material. For example, a non-magnetic material is not attracted by a magnet and has a relative permeability close to 1 with little to no remanence after field exposure. Examples of non-magnetic materials include aluminum, titanium, copper, ceramics (such as, concrete, Macor, and Pyrex), austenitic stainless steels such as, 304, 304L, and 316, and nickel alloys such as Inconel 600, Inconel 625, and Inconel 718. In embodiments, the sensor holder 25 is connected (directly or indirectly) to the pressure barrier 15 in a manner that defines the gap 100 between the sensor holder 25 and the pressure barrier 15. In one example, as illustrated in FIG. 1, a flange 115 that is connected to the sensor holder 25 is bolted or screwed 120 to the pressure barrier 15. Other types of connection may be used, including but not limited to welding, interference fit, and adhesive. In embodiments, the pressure barrier 15 has a first portion 125 and a second portion 130 that is relatively thinner than the first portion 125 in the direction of axis 70, and the gap 100 is defined between a first end of the sensor housing insert sub-assembly 20 and a wall of the second portion 130.

Implementations as described herein are suitable for use in subsea oil and gas well pump assemblies having design proof pressures up to 40,000 psi. Other applications include but are not limited to: runout measurements through walls; position measurement through walls; runout and position measurement in standard pressure port configurations such as AS5202; and pump speed sensing through pressure vessel walls.

As illustrated in FIG. 2, in embodiments the first sensor 35 is embedded in the sensor holder 25. For example, a notch, groove, or pocket may be formed in the sensor holder 25, wherein a base surface of the notch or groove lies in a plane that is perpendicular to the axis 65 and parallel to the axis 70.

As described herein, in a preferred embodiment, the second sensor 40 is identical to the first sensor 35. However, in some alternative embodiments, the second sensor 40 differs from the first sensor 35.

As described herein, in a preferred embodiment, the easy axis of the first sensor 35 is perpendicular to the magnetic field axis 65 of the biasing magnet 30. However, in some alternative embodiments, the easy axis of the first sensor 35 is purposefully set to a non-perpendicular orientation relative to the magnetic field axis 65 of the biasing magnet 30. In one example, the first sensor 35 is arranged in the sensor holder 25 such that the easy axis of the first sensor 35 is tilted by about 1 to 10 degrees from perpendicular to the magnetic field axis 65 of the biasing magnet 30. In some measurement applications, this small degree of tilt (e.g., away from perpendicular) improves the linearity and sensitivity of the sensor.

Further aspects of the invention include a method of manufacturing the sensor system 10 as described herein. Still further aspects of the invention include a method of installing and/or using the sensor system 10 relative to a target 60 for the purpose of detecting the displacement of the target 60 as described herein.

With continued reference to FIGS. 1 and 2, in one embodiment a sensor system comprises: a sensor holder 25 and a primary sensor 35 connected to a first end of the sensor holder 25, wherein a barrier 15 (which may be a pressure barrier or other type of barrier) extends between the first end of the sensor holder 25 and a target 60 with a gap 100 between the barrier 15 and the first end of the sensor holder 25, and wherein the primary sensor 35 comprises a magneto-resistive (MR) sensor that is configured to detect, through the barrier 15, relative motion between the target 60 and the sensor holder 25. The MR sensor may be one of a tunneling magneto-resistive (TMR) sensor, giant magneto-resistive (GMR) sensor, an anisotropic magneto-resistive (AMR) sensor, and a Hall-effect sensor. In this embodiment, the sensor system further comprises a biasing magnet 30, wherein an easy axis of the MR sensor is perpendicular to a magnetic field axis of the biasing magnet 30. The biasing magnet 30 may comprise one of a permanent magnet and an electro-magnet. The biasing magnet 30 may be connected to the sensor holder 25.

FIGS. 3-7 show embodiments of a sensor system that may include elements as described with respect to FIGS. 1 and 2, including but not limited to: barrier 15; sensor holder 25; biasing magnet 30; first (primary) sensor 35; second (compensating) sensor 40; signal conducting element 45; signal conditioning electronics; target 60; and gap 100. The biasing magnet(s) and sensor(s) shown in the embodiments of FIGS. 3-7 may be used to detect movement of the target in the same manner as described with respect to FIGS. 1 and 2. Sensor holder 25 shown in the embodiments of FIGS. 3-7 may be made of the same materials as sensor holder 25 described with respect to FIGS. 1 and 2 and may be configured to hold the sensor(s) 35 (and 40 if present) in the same manner as described with respect to FIGS. 1 and 2. Barrier 15 shown in the embodiments of FIGS. 3-7 may be made of the same materials as barrier 15 described with respect to FIGS. 1 and 2 and may be structured and arranged to withstand design proof pressures up to 40,000 psi (e.g., to maintain a gap between the barrier and the sensor holder) in the same manner as described with respect to FIGS. 1 and 2.

FIG. 3 shows an embodiment of a sensor system in accordance with aspects of the invention. As shown in the FIG. 3, the sensor system includes a biasing magnet 30, a primary sensor 35, at least one compensating sensor 40, and a compensating sensor biasing magnet 135 all connected to a sensor holder 25. In the sensor system shown in FIG. 3, a barrier 15 is between a first end of the sensor holder 25 and a target 60. As further shown in FIG. 3, the primary sensor 35 and the at least one compensating sensor 40 are operatively connected to a signal conducting element 45.

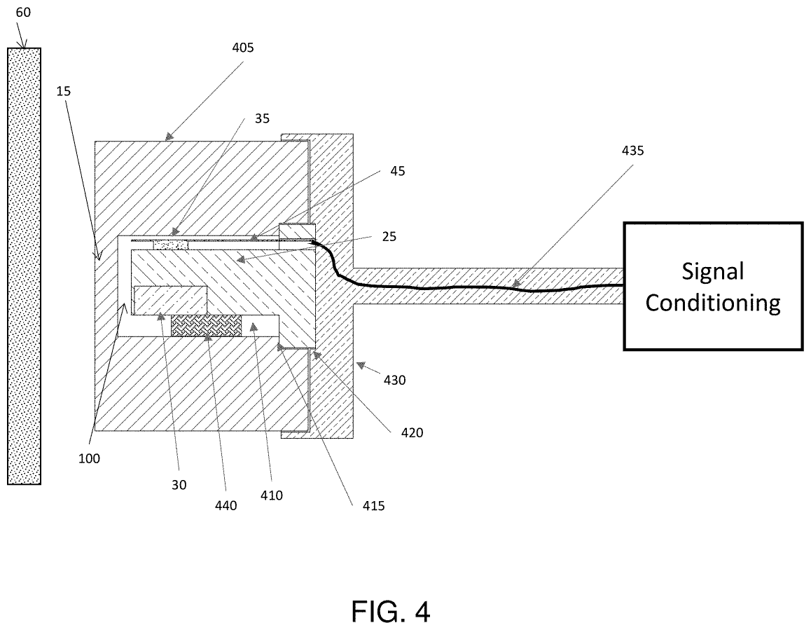

FIG. 4 shows an embodiment of a sensor system in accordance with aspects of the invention. As shown in FIG. 4, the sensor system includes a biasing magnet 30 and a primary sensor 35 connected to a sensor holder 25. In the sensor system shown in FIG. 4, a barrier 15 is between a first end of the sensor holder 25 and a target 60. As further shown in FIG. 4, the primary sensor 35 is operatively connected to a signal conducting element 45 that is connected to signal conditioning electronics. In the embodiment shown in FIG. 4, the barrier 15 is part of a housing 405 that defines a cavity 410. In this embodiment, the housing 405 comprises a shoulder 415 and the sensor holder 25 comprises a flange 420 that is configured to abut the shoulder 415 when the sensor holder 25 is fully inserted into the cavity 410. In this embodiment, the sensor holder 25 (including its flange 420) and the housing 405 (including its cavity 410 and shoulder 415) are sized and shaped such that the gap 100 is present when the sensor holder 25 is fully inserted into the cavity, i.e., with the flange 420 abutting the shoulder 415. As used in this specification and claims, elements that are described as abutting one another (e.g., abuts, abutting, etc.) may be in direct physical contact with one another or may optionally have a layer (e.g., a thin film) of potting material and/or adhesive material between the elements.

With continued reference to FIG. 4, in embodiments the sensor system comprises a bulkhead 430 that is configured to seal the sensor holder 25 inside the housing 405. In embodiments, in an assembled configuration, the bulkhead 430 is joined to the housing 405 by threaded connection, welding, or other physical joining method. In embodiments, in the assembled configuration, the bulkhead 430 abuts the second end of the sensor holder 25 such that the bulkhead holds the flange 420 in contact with the shoulder 415. In some embodiments, the joining of the bulkhead 430 to the housing 405 creates a hermetic seal around the sensor holder 25 inside the cavity 410.

Still referring to FIG. 4, in embodiments the sensor system includes a sensor signal wire 435 that operatively connects the signal conducting element 45 to the signal conditioning electronics. The sensor signal wire 435 may be a soft shielded line or armored cable or may be a hardline cable for hermetic construction. In embodiments, the sensor signal wire 435 is embedded in the bulkhead 430.

As further shown in FIG. 4, potting material 440 (or other stabilizing material) may be present in the cavity 410. In embodiments, the potting material 440 may fill portions of the cavity 410 between the first end and the second end of the sensor holder, but the potting material does not extend into the gap 100 (i.e., the gap 110 is devoid of the potting material 440).

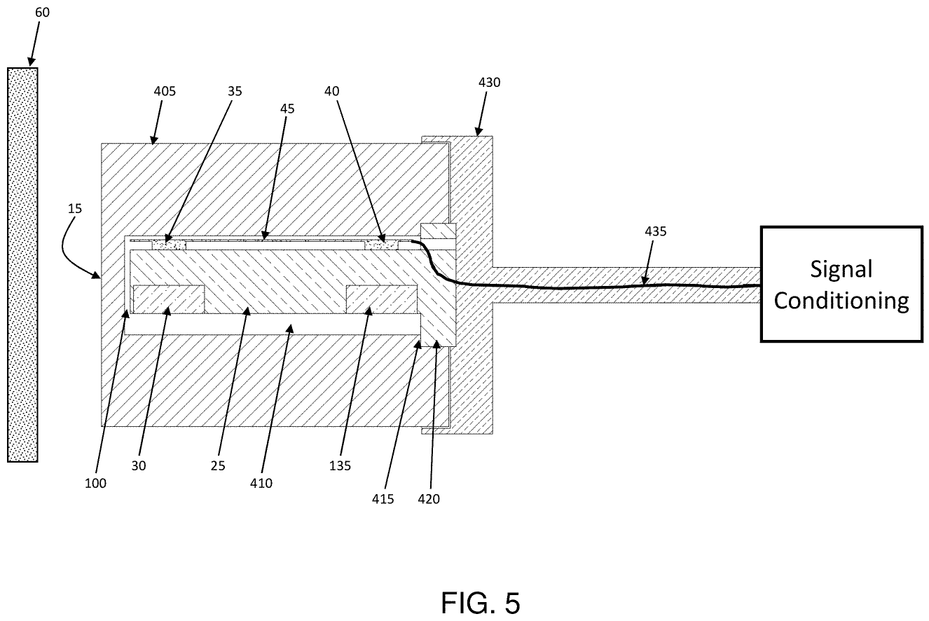

FIG. 5 shows an embodiment of a sensor system in accordance with aspects of the invention. The sensor system shown in FIG. 5 is similar to that shown in FIG. 4, and like reference numbers refer to similar elements. The sensor system shown in FIG. 5 additionally includes at least one compensating sensor 40 connected to the sensor holder 25 and the signal conducting element 45, and at least one compensating sensor biasing magnet 135 connected to the sensor holder 25. As described herein, the at least one compensating sensor biasing magnet 135 may be used to make the undisturbed magnetic environment of the at least one compensating sensor 40 closely match that of the undisturbed biased primary sensor environment. In this way, the effect of external disturbances on the at least one compensating sensor 40 more closely match that of the primary sensor 35.

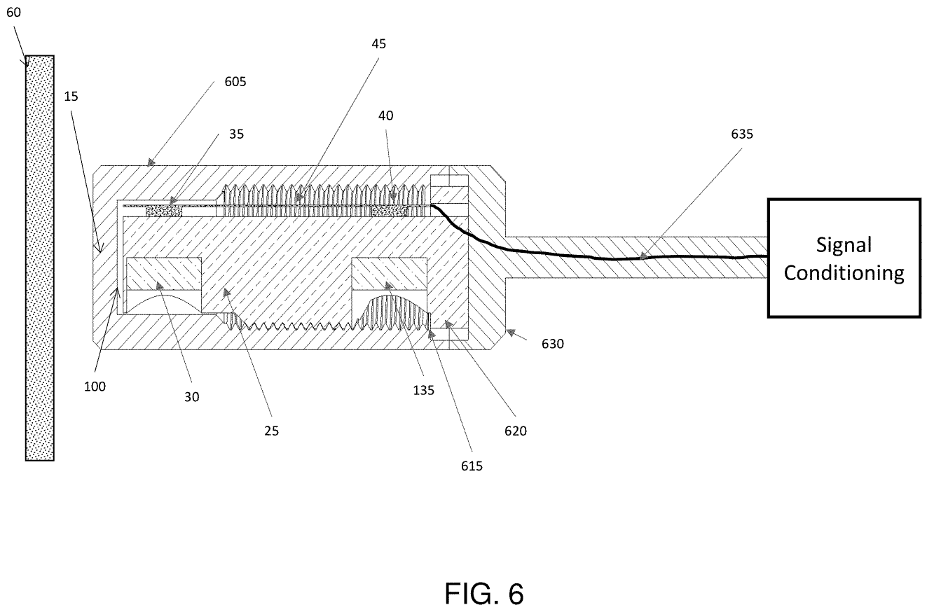

FIG. 6 shows an embodiment of a sensor system in accordance with aspects of the invention. As shown in the FIG. 6, the sensor system includes a biasing magnet 30, a primary sensor 35, at least one compensating sensor 40, and at least one compensating sensor biasing magnet 135 connected to a sensor holder 25. In the sensor system shown in FIG. 6, a barrier 15 is between a first end of the sensor holder 25 and a target 60. As further shown in FIG. 6, the primary sensor 35 and the at least one optional compensating sensor 40 are operatively connected to a signal conducting element 45 that is connected to signal conditioning electronics. In the embodiment shown in FIG. 6, the barrier 15 is part of a housing 605 that defines a cavity. In this embodiment, an interior surface of the housing 605 comprises threads that receive threads on an exterior surface of the sensor holder 25. Using these threaded surfaces, the sensor holder 25 is screwed into the cavity of the housing 605. In this embodiment, the housing 605 comprises a shoulder 615 and the sensor holder 25 comprises a flange 620 that is configured to abut the shoulder 615 when the sensor holder 25 is fully screwed into the cavity. In this embodiment, the sensor holder 25 (including its flange 620) and the housing 605 (including its cavity and shoulder 615) are sized and shaped such that the gap 100 is present when the sensor holder 25 is fully screwed into the cavity, i.e., with the flange 620 abutting the shoulder 615.

With continued reference to FIG. 6, in embodiments the sensor system comprises a bulkhead 630 that is configured to seal the sensor holder 25 inside the housing 605. In embodiments, in an assembled configuration, the bulkhead 630 is joined to the housing 605 by threaded connection, welding, or other physical joining method. In embodiments, in the assembled configuration, the bulkhead 630 abuts the second end of the sensor holder 25 such that the bulkhead holds the flange 620 in contact with the shoulder 615. In some embodiments, the joining of the bulkhead 630 to the housing 605 creates a hermetic seal around the sensor holder 25 inside the cavity.

Still referring to FIG. 6, in embodiments the sensor system includes a sensor signal wire 635 that operatively connects the signal conducting element 45 to the signal conditioning electronics. The sensor signal wire 635 may be a soft shielded line or armored cable or may be a hardline cable for hermetic construction. In embodiments, the sensor signal wire 635 is embedded in the bulkhead 630.

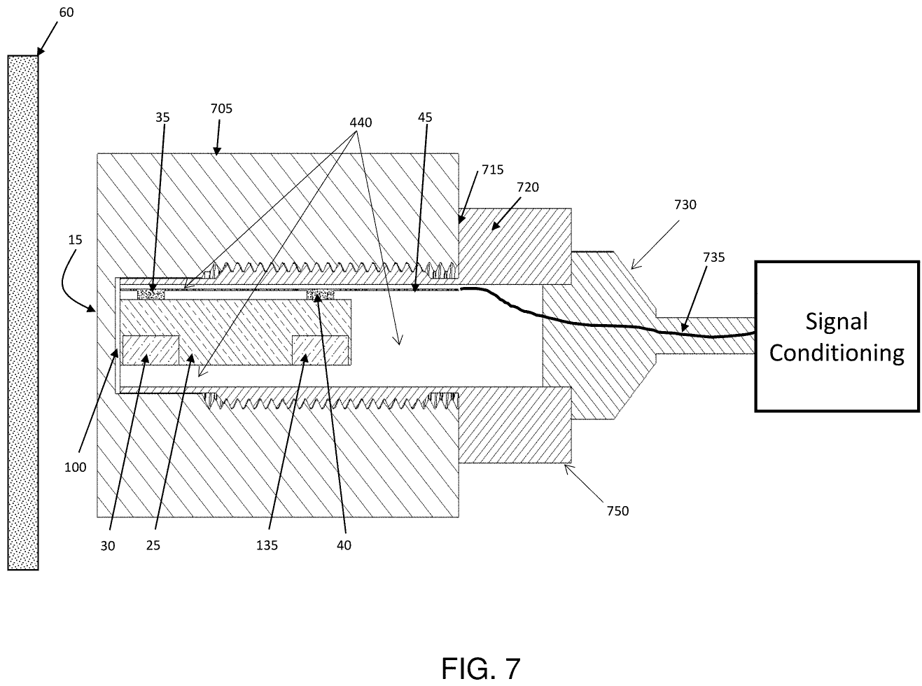

FIG. 7 shows an embodiment of a sensor system in accordance with aspects of the invention. As shown in the FIG. 7, the sensor system includes a biasing magnet 30, a primary sensor 35, at least one compensating sensor 40, and at least one compensating sensor biasing magnet 135 connected to a sensor holder 25. In the sensor system shown in FIG. 7, a barrier 15 is between a first end of the sensor holder 25 and a target 60. As further shown in FIG. 7, the primary sensor 35 and the at least one optional compensating sensor 40 are operatively connected to a signal conducting element 45 that is connected to signal conditioning electronics. In the embodiment shown in FIG. 7, the barrier 15 is part of a housing 705 that defines a cavity. In this embodiment, an interior surface of the housing 705 comprises threads that receive threads on an exterior surface of a sensor subassembly 750. Using these threaded surfaces, the sensor subassembly 750 is screwed into the cavity of the housing 705.

In the embodiment shown in FIG. 7, the sensor holder 25 is fully potted inside a cavity defined by the sensor subassembly 750. Notably, however, the potting material 440 does not extend into the gap 100 between the first end of the sensor holder 25 and the barrier 15. In a preferred embodiment, the potting material 440 contacts only the sensor subassembly 750 and does not contact the barrier 15 or any other portion of the housing 705.

Still referring to FIG. 7, in embodiments the housing 705 comprises a shoulder 715 and the sensor subassembly 750 comprises a flange 720 that is configured to abut the shoulder 720 when the sensor subassembly 750 is fully screwed into the cavity in the housing 705. In this embodiment, the sensor subassembly 750 (including its flange 720) and the housing 705 (including its cavity and shoulder 715) are sized and shaped such that the gap 100 is present when the sensor subassembly 750 is fully inserted into the cavity in the housing 705, i.e., with the flange 720 abutting the shoulder 715.

With continued reference to FIG. 7, in embodiments the sensor system comprises a bulkhead 730 that is configured to hold the sensor subassembly 750 against the housing 705.

Still referring to FIG. 7, in embodiments the sensor system includes a sensor signal wire 735 that operatively connects the signal conducting element 45 to the signal conditioning electronics. The sensor signal wire 735 may be a soft shielded line or armored cable or may be a hardline cable for hermetic construction. In embodiments, the sensor signal wire 735 is embedded in the bulkhead 730.

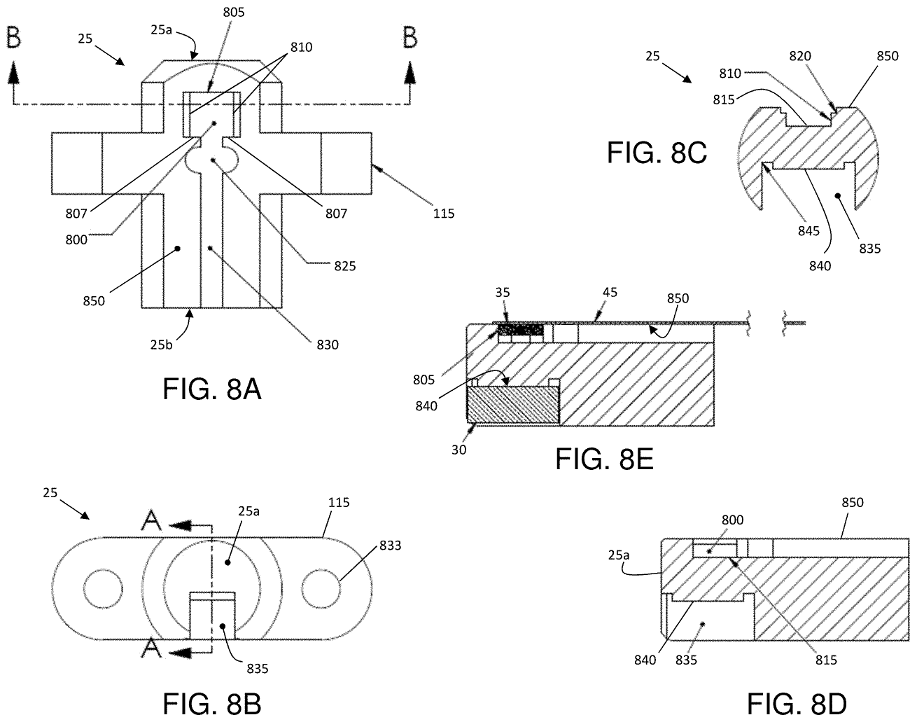

FIGS. 8A-E show aspects of a sensor holder 25 that may be used with a sensor system in accordance with aspects of the invention. Aspects described with respect to FIGS. 8A-E may be used in any sensor holder 25 described in FIGS. 1-7.

FIG. 8A shows a plan view of the sensor holder, e.g., looking downward along axis 65 as shown in FIG. 1. FIG. 8B shows an end view of the sensor holder, e.g., looking along axis 70 in a direction from the target 60 toward the sensor holder 25 as shown in FIG. 1. FIG. 8C shows a cross-section view along section A-A shown in FIG. 8A. FIG. 8D shows a cross-section view along section B-B shown in FIG. 8B. FIG. 8E shows a view similar to that of FIG. 8D, with elements connected to the sensor holder.

As shown in FIG. 8A, in embodiments the sensor holder 25 includes a body that defines a first pocket 800 that is configured to receive and hold the primary sensor 35. In accordance with aspects of the invention, the first pocket 800 locates and orients a chip (also referred to as a chip package) of the primary sensor 35 relative to the biasing magnet 30. The first pocket 800 may also be used to connect a chip package of the primary sensor 35 to the sensor holder 25 via potting material.

In embodiments, the sensor holder 25 has a first end 25a that is adjacent to the gap (e.g., gap 100) and a second end 25b opposite the first end 25a, with the first pocket 800 being closer to the first end 25a than the second end 25b. In embodiments, the first pocket 800 includes a forward position stop 805, an optional rearward position stop 807, sidewalls 810, and a bottom surface 815. As shown in FIG. 8C, the first pocket 800 may include a respective clearance feature (e.g., fillet clearance) 820 along the top portion of each sidewall 810.

In accordance with aspects of the invention, a chip package of the primary sensor 35 is configured to be held in the first pocket 800 with portions of the chip package abutting the position stop 805 and the sidewalls 810 in a close fitting manner to prevent unwanted movement of the chip within the first pocket 800. For example, sizing the first pocket 800 to have a close fit between the sidewalls 810 and the chip package prevents side-to-side movement and/or rotation of the chip package within the first pocket 800 and with respect to the line of target motion (e.g., axis 70). Also, abutting the chip package against the forward position stop 805 and/or the rearward position stop 807 provides a structural feature to precisely control the backward and forward location of the chip package along the line of target motion (e.g., axis 70).

The depth of the first pocket 800 may be varied depending on the type of signal conducting element 45 used. For example, when the signal conducting element 45 is a PCB, a chip package of the primary sensor 35 may be connected to and held by the PCB in such a manner that the chip package does not contact the bottom surface 815. In this arrangement, potting material may be provided between the chip package and the bottom surface 815. As another example, when the signal conducting element 45 is something other than a PCB (e.g., such as a wire), a chip package of the primary sensor 35 may abut or sit directly on the bottom surface 815.

With continued reference to FIG. 8A, the sensor holder 25 may optionally include one or both of a signal conditioning pocket 825 and a potting groove 830. In embodiments when the signal conducting element 45 is something other than a PCB (e.g., such as a wire), the potting groove 830 provides a path for signal wires that may be soldered to the primary sensor 35 held in the first pocket 800. In embodiments when the signal conducting element 45 is a PCB, the potting groove 830 provides a groove for adhesive that holds the PCB to the sensor holder 25. In embodiments, the sensor holder 25 comprises a flat upper surface 850 that is used as a seat for a PCB when the signal conducting element 45 is a PCB. In this manner, the flat upper surface 850 contributes to controlling the height of the primary sensor 35 over the biasing magnet 30.

As shown in FIGS. 8A and 8B, the sensor holder 25 may include a flange 115 or other datum/position control and integration feature. The flange 115 may include a bore 833 configured to receive a bolt or screw, e.g., in the manner shown in FIG. 1.

Referring now to FIGS. 8B-D, in embodiments the sensor holder 25 includes a second pocket 835 that is configured to receive and hold the biasing magnet 35. In accordance with aspects of the invention, the second pocket 835 retains the biasing magnet and ensures a proper orientation and position of the magnetic axis (e.g., axis 65) with respect to the chip package of the primary sensor 35. In embodiments, the second pocket 835 intersects the first end 25a of the sensor holder 25. In embodiments, the second pocket 835 includes a flat surface 840 that the biasing magnet 30 abuts when the biasing magnet 30 is in the second pocket 835. In embodiments, there may optionally be a layer (e.g., a thin film) of potting material and/or adhesive between the biasing magnet 30 and the flat surface 840. The second pocket 835 may optionally include grooves 845 at the corners to ensure that the biasing magnet 30 sits flat against the flat surface 840. Optionally, a potting material and/or adhesive material may be present in the second pocket 835, e.g., around the biasing magnet 30 and/or in the grooves 845, to securely retain the biasing magnet 30 in the second pocket 835.

FIG. 8E shows the view of FIG. 8D with a primary sensor 35 contained in the first pocket and a biasing magnet 30 contained in the second pocket of the sensor holder 25. In the implementation shown in FIG. 8E, the signal conducting element 45 comprises a PCB and the primary sensor 35 comprises a chip package connected to the PCB. As shown in the exemplary implementation of FIG. 8E, the PCB sits on the flat upper surface 850, with the chip package of the primary sensor 35 being suspended downward from the PCB into the first pocket and abutting the position stop 805. As further shown in the exemplary implementation of FIG. 8E, the biasing magnet 30 is held in the second pocket against the flat surface 840.

The response of an MR sensor in displacement measuring applications is dependent on the location and orientation of the magnet with respect to the sensing elements contained within the chip package. Therefore, to achieve the desired level of performance in a manufacturable configuration, the position and orientation of the chip package and the magnet are controlled and configured in embodiments in such a way to minimize size and allow a pathway for the signal from the sensor holder assembly out to signal processing hardware.

As described herein, in some embodiments the signal conducting element 45 comprises a PCB and the primary sensor 35 comprises a chip connected to the PCB, while in other embodiments the signal conducting element 45 comprises something other than a PCB (e.g., wires soldered directly to a chip package of the primary sensor 35). In the first case, the PCB may act as a position control feature wherein the PCB abuts the flat upper surface 850 of the sensor holder 25 thereby setting the height of the primary sensor 35 above the biasing magnet 30. In the second case, leads soldered directly to the pads of the chip package of the primary sensor 35 may be are routed through the potting groove 830. In the second case, a surface of the chip package abuts the bottom surface 815 of the first pocket 800. In the first case, the flat upper surface 850 controls the vertical position of the chip package and there is clearance between the chip package and the bottom surface 815 of the first pocket 800, whereas in the second case, the chip package abuts the bottom surface 815 of the first pocket 800 such that the bottom surface 815 of the first pocket 800 controls the vertical position of the chip package.

In embodiments, for forward and backward assembly position control, the chip package is installed so that either the front or back edge of the chip package abuts sensor chip position stop, such as position stop 805. In embodiments, the two sidewalls 810 prevent rotation of the chip package to ensure the sensor's easy axis is in alignment with the position measurement direction. In embodiments, side-to-side and forward-backward position control features ensure that the sensing elements are located within a specified tolerance zone about the axis of the biasing magnet 30.

In embodiments, the biasing magnet 30 abuts the bottom surface 840 of the second pocket 835. The corners of the second pocket 835 may have a machined groove 845 so that there is no interference between the biasing magnet 30 and the sensor holder 25 in the corners of the second pocket 835. In embodiments, the second pocket 835 location is such that the magnetic field axis of the biasing magnet 30 is aligned with the sensing elements of the chip package and at an orientation favorable to the needs of the measuring application. For example, in some instances the magnetic field axis is perpendicular to the PCB mounting surface, whereas in other instances it may be desirable to cant the magnetic field axis in a favorable direction by up to 10 degrees to achieve an improved response based on the measurement objectives.

In embodiments, to accommodate soldered connections to the chip package, the first pocket 800 may have an additional clearance feature 820 to allow clearance for any solder fillet. In embodiments, solder fillet clearance feature 820 also prevents shorting of the sensor leads in cases where the sensor holder 25 is made from an electrically conductive material.

In accordance with aspects of the invention, the second pocket 835 in combination with the first pocket 800 controls the distance, or spacing, between the primary sensor 35 and the biasing magnet 30. In embodiments, this distance varies depending on the size of the biasing magnet 30, the sensor specification of the primary sensor 35, and the requirements of the measurement. However, most generally this spacing is chosen to maximize the response of the primary sensor 35 to the given sensing environment. The first pocket 800 and the second pocket 835 may be duplicated on the sensor holder as needed to accommodate one or more additional sensors and magnets, such as a compensating sensor 40 and compensating sensor biasing magnet 135.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed:

1. A sensor system, comprising:
a sensor holder;
a primary sensor connected to the sensor holder at a first end of the sensor holder; and
a biasing magnet connected to the sensor holder at the first end of the sensor holder,
wherein a barrier extends between the first end of the sensor holder and a target with a gap between the barrier and the first end of the sensor holder; and
the primary sensor comprises a magneto-resistive (MR) sensor that is configured to detect, through the barrier, relative motion between the target and the sensor holder.

2. The sensor system of claim 1, wherein:
the barrier is comprised in a housing; and
the sensor holder is connected to the housing.

3. The sensor system of claim 2, wherein:
the housing defines a cavity; and
the sensor holder is inside the cavity.

4. The sensor system of claim 3, wherein:
a portion of the cavity is filled with a potting material; and
the gap is devoid of the potting material.

5. The sensor system of claim 1, wherein:
a second end of the sensor holder comprises a structural element that abuts a portion of the housing; and
the second end of the sensor holder is opposite the first end of the sensor holder.

6. The sensor system of claim 5, wherein the structural element that abuts a portion of the housing defines the gap by limiting a distance that the sensor holder is inserted into the housing.

7. The sensor system of claim 5, further comprising a bulkhead connected to the housing and contacting the second end of the sensor holder.

8. The sensor system of claim 7, wherein the bulkhead covers the second end of the sensor holder such that the sensor holder is completely enclosed by the housing and the bulkhead.

9. The sensor system of claim 1, further comprising a sensor subassembly structured and arranged to be connected to a housing that includes the barrier, wherein the sensor holder is in a cavity in the sensor subassembly.

10. The sensor system of claim 9, wherein a portion of the sensor subassembly abuts a portion of the housing and defines the gap by limiting a distance that the sensor holder is inserted into the housing.

11. The sensor system of claim 9, wherein:
a portion of the cavity is filled with a potting material; and
the gap is devoid of the potting material.

12. The sensor system of claim 1, wherein the gap has a dimension in a range of 1 mil to 20 mils.

13. The sensor system of claim 1, wherein the barrier is constructed of a material and with a geometry such that the barrier does not deflect into contact with the sensor holder when a design proof pressure of up to 40,000 psi is applied to a target side of the barrier relative to a sensor side of the barrier.

14. The sensor system of claim 1, wherein the primary sensor is connected to a printed circuit board.

15. The sensor system of claim 1, further comprising at least one compensating sensor connected to the sensor holder.

16. The sensor system of claim 15, wherein the sensor system cancels ambient magnetic field disturbances from an output of the primary sensor using an output of the at least one compensating sensor.

17. The sensor system of claim 15, wherein the at least one compensating sensor is located a distance away from the primary sensor such that the compensating sensor does not detect, to a significant degree, the magnetic field interaction between a biasing magnet and the target.

18. The sensor system of claim 1, wherein the primary sensor is received in a pocket in the sensor holder, the pocket including sidewalls and a position stop that define a position of the primary sensor relative to the biasing magnet.

19. A sensor system, comprising:
a sensor holder in a cavity of a housing; and
a primary sensor connected to the sensor holder at a first end of the sensor holder;
wherein the housing comprises a barrier extending between the first end of the sensor holder and a target with a gap between the barrier and the first end of the sensor holder;
a second end of the sensor holder abuts the housing, the second end of the sensor holder being opposite the first end of the sensor holder; and
the primary sensor comprises a magneto-resistive (MR) sensor that is configured to detect, through the barrier, relative motion between the target and the sensor holder.

20. A sensor system, comprising:
a sensor holder;
a primary sensor connected to the sensor holder at a first end of the sensor holder; and
at least one compensating sensor connected to the sensor holder,
wherein a barrier extends between the first end of the sensor holder and a target with a gap between the barrier and the first end of the sensor holder;
the primary sensor comprises a magneto-resistive (MR) sensor that is configured to detect, through the barrier, relative motion between the target and the sensor holder; and
the sensor system cancels ambient magnetic field disturbances from an output of the primary sensor using an output of the at least one compensating sensor.
